(19) United States
(12) Patent Application Publication
(10) Pub. No.: US 2025/0062149 A1
(43) Pub. Date: Feb. 20, 2025

(54) ELECTROSTATIC CHUCKS WITH SELF-SEALING GAS CONDUITS AND/OR REDUCED CLOGGING DUE TO RESIDUE

(71) Applicant: LAM RESEARCH CORPORATION, Fremont, CA (US)

(72) Inventors: Kadthala R. NARENDRNATH, San Jose, CA (US); Behnam BEHZIZ, Newark, CA (US); Benny WU, Fremont, CA (US); Moreshwar Narayan PURANDARE, San Jose, CA (US)

(21) Appl. No.: 18/721,910

(22) PCT Filed: Dec. 15, 2022
(86) PCT No.: PCT/US2022/052990

§ 371 Date: Jun. 20, 2024

Related U.S. Application Data
(60) Provisional application No. 63/292,743, filed on Dec. 22, 2021.

(51) Int. Cl. H01L 21/683; H01J 37/32; H01L 21/687

(52) U.S. Cl. CPC H01L 21/6833; H01L 21/68757; H01L 21/68785; H01J 37/32724

(57) ABSTRACT

An electrostatic chuck for a substrate includes a baseplate including a first surface and a cavity arranged on the first surface. A top plate includes a first plug. A first spring member is arranged in the cavity. A second plug is arranged between the top plate and the first spring member. A bonding material attaches the top plate to the first surface of the baseplate.

### CROSS-REFERENCE TO RELATED APPLICATIONS

This application claims the benefit of U.S. Provisional Application No. 63/292,743, filed on Dec. 22, 2021. The entire disclosure of the above application is incorporated herein by reference.

### FIELD

The present disclosure relates generally to substrate processing systems and more particularly to electrostatic chucks with self-sealing gas conduits and/or reduced clogging due to residue.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Semiconductor processing systems are used to treat substrates such as semiconductor wafers. Examples of substrate treatments include deposition, etching, cleaning and/or other treatments. During processing, one or more process gases are supplied to the processing chamber and plasma is struck in the processing chamber to promote chemical reactions.

The processing chamber includes an electrostatic chuck (ESC) to hold the substrate in place during processing. The ESC includes clamping electrodes that are energized to hold the substrate against a top plate of the ESC and de-energized when loading or removing the substrate from the ESC. The ESC may also include resistive heaters embedded in the top plate and/or cooling channels in the baseplate to control the temperature of the substrate during processing and reduce processing non-uniformity. To increase thermal uniformity, the ESC supplies an inert gas (such as helium (He)) to a back side surface of the substrate. The inert gas acts as a thermal transfer medium between the top plate and the backside surface of the substrate.

### SUMMARY

An electrostatic chuck for a substrate includes a baseplate including a first surface and a cavity arranged on the first surface. A top plate includes a first plug. A first spring member is arranged in the cavity. A second plug is arranged between the top plate and the first spring member. A bonding material attaches the top plate to the first surface of the baseplate.

In other features, the first spring member biases the second plug into direct contact with a second surface of the top plate and wherein the top plate, the first plug and the second plug are made of ceramic. A gasket is arranged around the cavity between the top plate and the baseplate. The bonding material is located radially outside of the gasket. The first plug is made of porous ceramic and is formed insitu in the top plate. The second plug is made of porous ceramic. The second plug has a diameter that is greater than a diameter of the first plug.

In other features, the second plug includes an annular outer channel formed on a radially outer surface thereof to receive the bonding material. The second plug is made of porous ceramic and does not include a gas through-hole. The second plug is made of porous ceramic and includes a gas through-hole that extends partially through the second plug. The second plug is made of porous ceramic and includes a gas through-hole that extends through the second plug.

In other features, the second plug includes a cylindrical body with a radially outer portion made of non-porous ceramic and a radially inner portion made of porous ceramic. A sleeve is arranged between the second plug and side surfaces of the cavity. A second spring member is arranged in the cavity to bias the sleeve against the top plate. The second plug is made of porous ceramic. The sleeve is made of ceramic.

A method of making an electrostatic chuck for a substrate includes providing a baseplate including a first surface and a cavity arranged on the first surface; providing a top plate including a first plug; arranging a first spring member in the cavity; arranging a second plug between the top plate and the first spring member; and attaching the top plate to the first surface of the baseplate using a bonding material.

In other features, the method includes biasing the second plug into direct contact with a second surface of the top plate using the first spring member. The top plate, the first plug and the second plug are made of ceramic. The method includes arranging a gasket around the cavity between the top plate and the baseplate prior to using the bonding material. The method includes forming the first plug insitu in the top plate. The first plug is made of porous ceramic.

In other features, the second plug is made of porous ceramic. The second plug has a diameter that is greater than a diameter of the first plug. The method includes forming an annular channel on a radially outer surface of the second plug to receive the bonding material. The second plug is made of porous ceramic and does not include a gas through-hole. The second plug is made of porous ceramic and includes a gas through-hole extending partially through the second plug. The second plug is made of porous ceramic and includes a gas through-hole extending through the second plug. The second plug includes a cylindrical body with a radially outer portion made of non-porous ceramic and a radially inner portion made of porous ceramic.

In other features, the method includes arranging a sleeve between the second plug and side surfaces of the cavity. The method includes biasing the sleeve against the top plate using a second spring member. The second plug is made of porous ceramic. The sleeve is made of ceramic.

An electrostatic chuck for a substrate includes a baseplate including a first surface and a cavity arranged on the first surface. The cavity includes a first cavity portion defining a first annular surface and a second cavity portion defining a second annular surface. A top plate includes a first plug. A first spring member is arranged on the first annular surface in the first cavity portion. A second plug is arranged on the second annular surface between the top plate and the second annular surface. A sleeve is arranged around the second plug and on the first spring member. A bonding material attaches the top plate to the first surface of the baseplate.

In other features, the first spring member biases a top surface of the sleeve into direct contact with a bottom surface of the top plate. A gasket is arranged around the cavity between the top plate and the baseplate, wherein the bonding material is located radially outside of the gasket. The first plug is made of porous ceramic and is formed insitu in the top plate. The second plug has a diameter that is greater than a diameter of the first plug.

In other features, bonding material bonds the second plug to side walls of the second cavity portion. The second plug is made of porous ceramic and does not include a gas through-hole. The second plug is made of porous ceramic and includes a gas through-hole that extends partially through the second plug. The second plug is made of porous ceramic and includes a gas through-hole that extends through the second plug. The second plug is made of non-porous ceramic and includes a gas through-hole that extends through the second plug.

A method for making an electrostatic chuck for a substrate includes providing a baseplate including a first surface and a cavity arranged on the first surface, wherein the cavity includes a first cavity portion defining a first annular surface and a second cavity portion defining a second annular surface; providing a top plate including a first plug; arranging a first spring member on the first annular surface in the first cavity portion; arranging a second plug on the second annular surface between the top plate and the second annular surface; arranging a sleeve around the second plug and on the first spring member; and bonding the top plate to the first surface of the baseplate.

In other features, the method includes biasing the sleeve into direct contact with a bottom surface of the top plate using the first spring member. A gap is defined between a top surface of the second plug and the bottom surface of the top plate when the top plate is bonded to the baseplate. The method includes arranging a gasket around the cavity between the top plate and the baseplate, wherein bonding material is located radially outside of the gasket. The first plug is made of porous ceramic and is formed insitu in the top plate. The second plug has a diameter that is greater than a diameter of the first plug. The second plug is made of porous ceramic and does not include a gas through-hole. The second plug is made of porous ceramic and includes a gas through-hole that extends one of partially through the second plug and through the second plug. The second plug is made of non-porous ceramic and includes a gas through-hole that extends through the second plug. The method includes bonding the second plug to side walls of the second cavity portion.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a processing chamber of a substrate processing system including an electrostatic chuck according to the present disclosure;

FIG. 2 is a side cross-sectional view of an example of an electrostatic chuck (ESC);

FIG. 3 is a side cross-sectional view of an example of an ESC with self-sealing gas conduits and/or reduced clogging due to residue according to the present disclosure;

FIGS. 4-7 are side cross-sectional views of other examples of ESCs with self-sealing gas conduits and/or reduced clogging due to residue according to the present disclosure;

FIG. 8 is a flowchart illustrating an example of a method for making an ESC with self-sealing gas conduits and/or reduced clogging due to residue according to the present disclosure;

FIGS. 9-10 are side cross-sectional views of other examples of ESCs with self-sealing gas conduits and/or reduced clogging due to residue according to the present disclosure; and

FIG. 11 is a flowchart illustrating an example of another method for making an ESC with self-sealing gas conduits and/or reduced clogging due to residue according to the present disclosure.

In the drawings, reference numbers may be reused to identify similar and/or identical elements.

### DETAILED DESCRIPTION

An electrostatic chuck (ESC) according to the present disclosure includes self-sealing gas conduits and/or reduced clogging due to residue. The ESC includes a top plate including a first plug. The top plate is attached to a baseplate including a cavity using bonding material or bonding material and a gasket. One or more spring members are arranged in the cavity. A second plug is arranged in the cavity on the one or more spring members. The second plug is biased by the one or more spring members against a bottom surface of the top plate.

The ESC with self-sealing gas conduits and/or reduced clogging due to residue according to the present disclosure eliminates a gap between the bottom surface of the top plate and/or the first plug and the top surface of the second plug. In other words, the top plate and/or the first plug directly contact the second plug. The ESC according to the present disclosure reduces the ability of reactive species to reach and erode the gasket and/or the bonding material, which reduces the production of residue. The ESC arrangement also significantly reduces or eliminates clogging or substantially nullifies the negative effects of clogging to enable the ESC to continue to provide sufficient inert gas flow between the substrate and the top plate over the lifetime of the ESC. More particularly, if clogging occurs, the clogging is limited to areas that do not adversely impact inert gas flow.

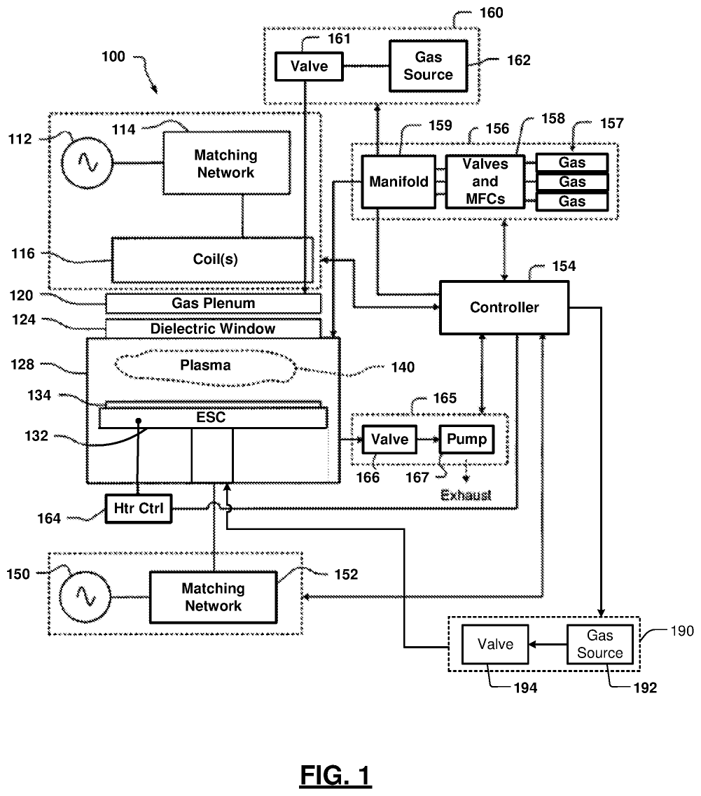

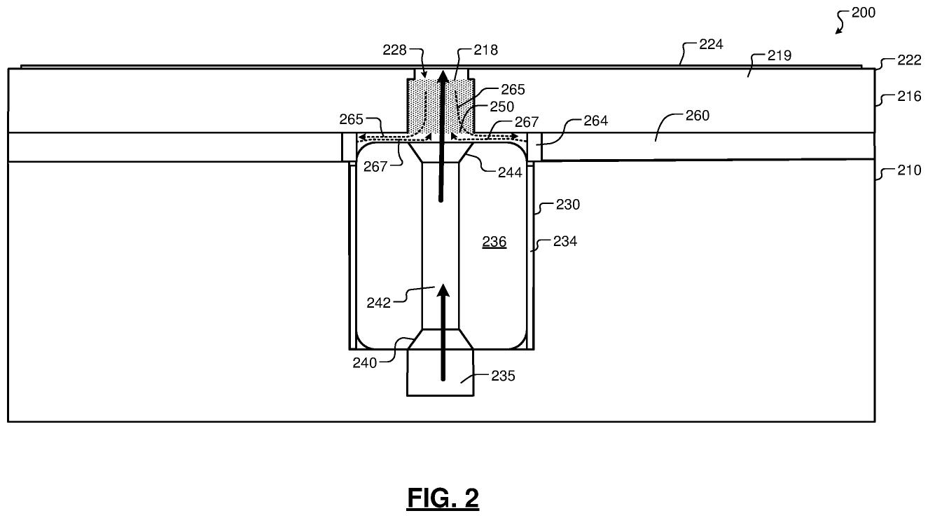

Referring now to FIG. 1, an example of a substrate processing system 100 including an electrostatic chuck (ESC) according to the present disclosure is shown. While the substrate processing system in FIG. 1 uses inductively coupled plasma (ICP), the ESC according to the present disclosure can be used with other types of substrate processing chambers (such as those using capacitively coupled plasma (CCP)). The substrate processing system 100 includes an RF source 112 connected to a matching network 114, which is connected to coils 116. The coils 116 may include a single coil, a pair of coils, an inner coil pair and an outer coil pair, and/or other coil arrangements.

In some examples, a gas plenum 120 may be arranged between the coils 116 and a dielectric window 124. The dielectric window 124 is arranged along one side of a processing chamber 128. The processing chamber 128 further comprises an electrostatic chuck (ESC) 132 that supports a substrate 134. The ESC 132 includes self-sealing gas conduits and/or reduced clogging due to residue as will be described below in further detail below.

During processing, plasma 140 is generated inside of the processing chamber 128. The plasma 140 etches an exposed surface of the substrate 134. An RF source 150 and a matching network 152 may be used to bias the ESC 132 during operation. A gas delivery system 156 may be used to supply a gas mixture to the processing chamber 128. The gas delivery system 156 may include process gas sources 157, a metering system 158 such as valves and mass flow controllers (MFCs), and a manifold 159. A gas delivery system 160 may be used to deliver gas 162 via a valve 161 to the gas plenum 120. The gas may include cooling gas that is used to cool the coils 116 and the dielectric window 124.

A heater controller 164 may be used to supply power to resistive heaters (not shown) in the ESC 132 to a control a temperature of the substate within a predetermined temperature range during processing. A baseplate of the ESC 132 may also include one or more cooling channels to receive a cooling fluid (not shown). An exhaust system 165 includes a valve 166 and pump 167 to remove reactants from the processing chamber 128 by purging or evacuation. A controller 154 may be used to control the etching process. The controller 154 monitors system parameters and controls delivery of the gas mixture, striking, maintaining and extinguishing the plasma, removal of reactants, supply of cooling gas, etc.

A gas delivery system 190 may be used to deliver gas 192 via a valve 194 to the ESC 132. The ESC 132 delivers the gas to a backside surface of the substrate 134 as will be described further below. The gas may include an inert gas that acts as a thermal transfer medium between the top plate of the ESC 132 and the backside surface of the substrate 134.

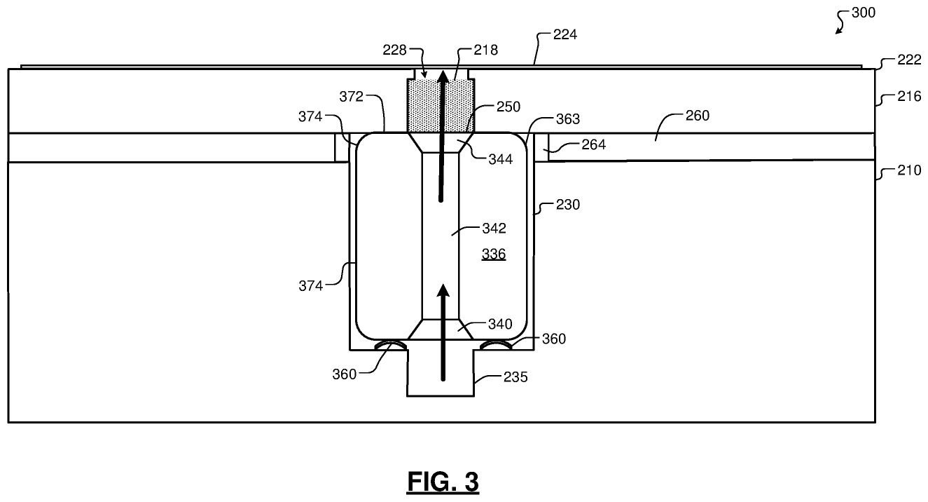

Referring now to FIG. 2, an ESC 200 that does not include self-sealing gas conduits or reduced clogging due to residue is shown for purposes of illustration. The ESC 200 includes a baseplate 210 and a top plate 216. The top plate 216 has a cylindrical shape and includes a first plug 218 that is located insitu in a center of the top plate 216. In some examples, the top plate 216 and the first plug 218 are made of ceramic, although other materials can be used. In some examples, the first plug 218 also has a cylindrical shape, although other shapes can be used. In some examples, the top plate 216 includes an annular outer portion 219 that is made of ceramic that is non-porous or less porous than the first plug 218 and the first plug is made of porous ceramic to allow gas flow. A substrate 224 is arranged on the top plate 216 during processing.

A top surface 228 of the first plug 218 is shown recessed relative to a top surface of the top plate 216. However, the first plug 218 can extend to the top surface of the top plate 216. The top surface of the top plate 216 may include a pattern of gas channels (not shown) to control flow of the inert gas below the substrate 224. The baseplate 210 includes a cavity 230 that extends vertically downward from a top surface of the baseplate 210. The cavity 230 is located below the top plate 216 and/or the first plug 218. In some examples, the cavity 230 has a cylindrical shape. The ESC 200 includes a second plug 236 that is arranged in the cavity 230. In some examples, a bonding material 234 such as a polymer may be used to bond an outer surface of the second plug 236 to an inner surface of the cavity 230.

In some examples, the second plug 236 is made of solid ceramic and includes a gas through-hole 242 that extends vertically. In some examples, the baseplate 210 is made of aluminum, although other materials can be used. In some examples, an inlet 240 and an outlet 244 of the gas through-hole 242 are widened, angled and/or chamfered relative to a diameter of the gas through-hole 242 as shown. In some examples, a bottom surface of the cavity 230 in the baseplate 210 may further include a cavity 235 that is located below the inlet 240 of the second plug 236. Inert gas flows into the cavity 235, through the gas through-hole 242 in the second plug 236, through pores in the first plug 218 and between the backside surface of the substrate 224 and the top surface of the top plate 216.

During assembly, the second plug 236 is inserted into the cavity 230 of the baseplate 210 and attached to an inner surface of the cavity 230 using the bonding material 234. The top plate 216 is oriented relative to the baseplate 210 and attached to the top surface of the baseplate 210 using a bonding material 260. In some examples, a gasket 264 may be used to prevent the bonding material 260 from flowing or being squeezed into the cavity 230 of the baseplate 210 prior to curing of the bonding material 260.

The top plate 216 is positioned with a very high degree of accuracy relative to the baseplate 210. In other words, the top plate 216 is precisely oriented relative to the baseplate 210 to ensure a level surface for processing the substrate 224 and to prevent tilt. Since the bonding material 260 can have a variable height, a predetermined non-zero gap is defined between a top surface of the second plug 236 and a bottom surface 250 of the first plug 218 to prevent the second plug 236 from affecting the location and orientation of the top plate 216 relative to the baseplate 210.

As described above, the top plate 216 of the ESC 200 includes the first plug 218 that is porous. The porous material of the first plug 218 reduces line of sight paths and helps to break electric field lines. This approach helps to prevent electrons from picking up sufficient energy from the electric fields to cause light-up. However, the first plug 218 and other backside gas pathways can become clogged over time. The predetermined non-zero gap that is used between the top surface of the second plug 236 and the bottom surface 250 of the first plug 218 provides a path for the reactive species to reach the bonding materials 234 and 260 and/or the gasket 264. Over time, gas pathways of the ESC 200 become blocked by the residue, which reduces flow or changes flow paths of the inert gas to the backside surface of the substrate and adversely impacts cooling of the substrates.

For example, the bonding materials 234 and 260 and/or the gasket 264 are eroded by exposure to reactive species during processing (as indicated by arrows 265). Residue due to the erosion of the bonding materials 234 and 260 and/or the gasket 264 (as indicated by arrows 267) is drawn into pores of the first plug 218 and/or the second plug 236 causing blockage. The reduced gas flow due to the clogged pores of the first plug 218 adversely affects substrate thermal uniformity, which reduces die yield and customer productivity and increases cost.

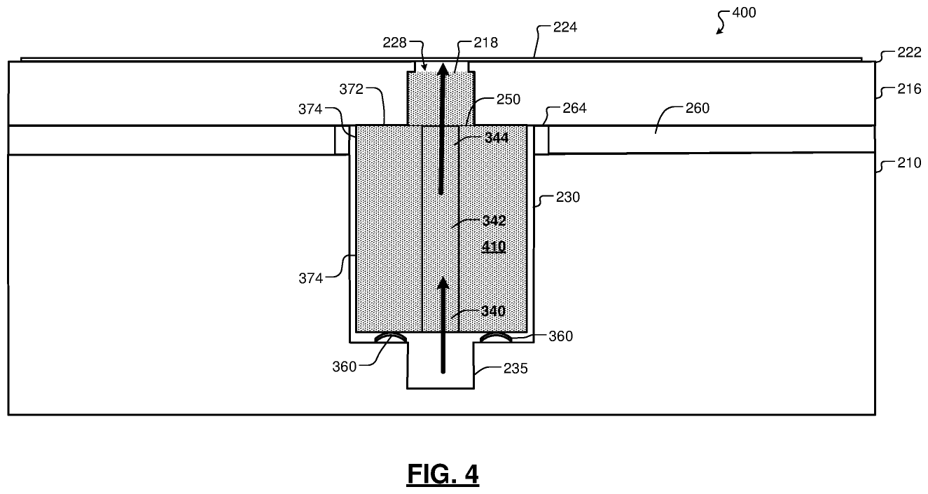

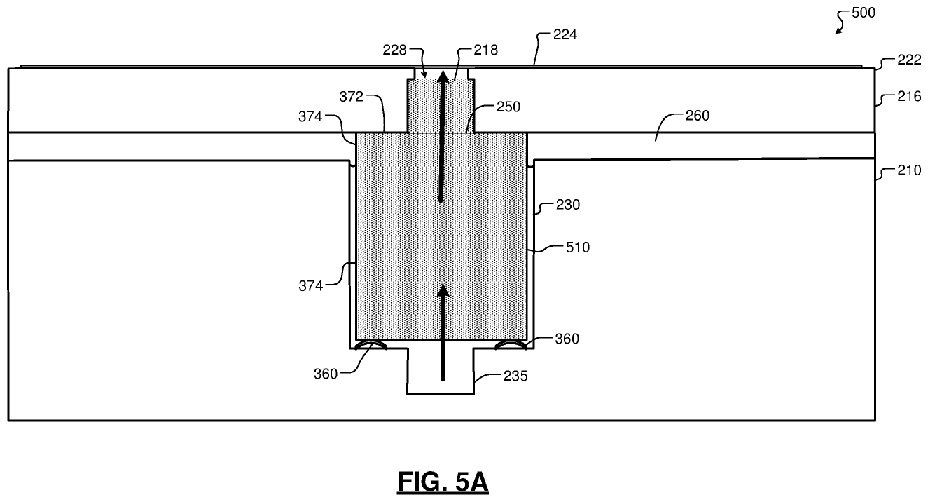

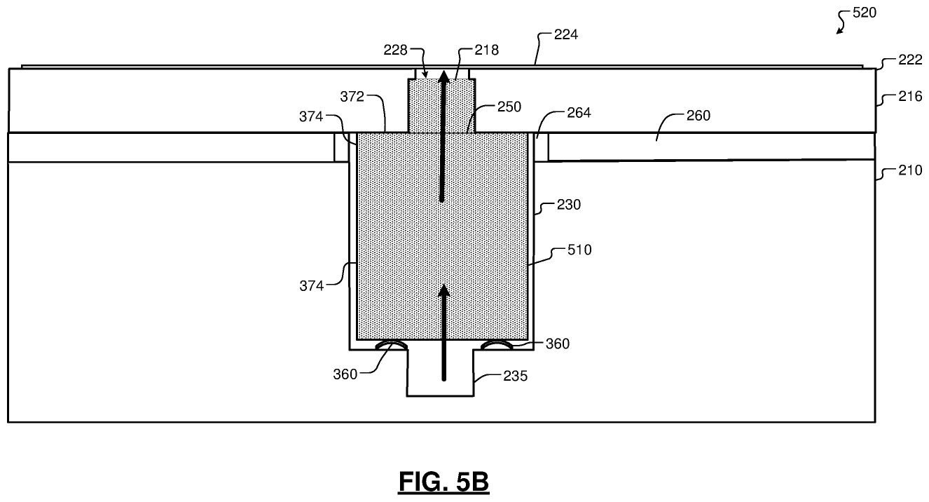

Referring now to FIGS. 3 and 4, examples of ESCs that have improved gas flow and reduced clogging are shown. In FIG. 3, an ESC 300 includes a second plug 336 that is arranged in the cavity 230. The second plug 336 has a cylindrical body with a diameter that is greater than a diameter of the first plug 218.

One or more spring members 360 are located on a bottom surface of the cavity 230. In some examples, the one or more spring members 360 have an annular shape and are made of polymer, metal or other suitable materials. This arrangement eliminates the gap between the second plug 336 and the top plate 216 as shown in FIG. 2. In some examples, adhesive is not used between an inner surface of the cavity 230 and an outer surface of the second plug 336 to allow relative movement during assembly.

Once assembled, a top surface of the second plug 336 is in direct contact with a bottom surface of the first plug 218. As a result, the location of possible clogging is moved radially outwardly away from the inert gas flow path. In some examples, the second plug 336 is made of non-porous ceramic and includes a partial or complete gas through-hole 342. In some examples, an inlet 340 and an outlet 344 of the gas through-hole 342 may be angled or chamfered as shown relative to a diameter of the gas through-hole 342. Inert gas flows through the gas through-hole 342 in the second plug 336, through pores in the first plug 218 and between the backside surface of the substrate 224 and a top surface of the top plate 216. The top surface of the top plate 216 may include a pattern of gas channels (not shown) to direct the flow of inert gas below the substrate.

During assembly, the one or more spring members 360 are arranged in the cavity 230 of the baseplate 210. The second plug 336 is inserted into the cavity 230 of the baseplate 210 with a bottom surface thereof in contact with the one or more spring members 360. The top plate 216 is attached to the top surface of the baseplate 210 using the bonding material 260 and the bonding material 260 is cured. The top plate 216 biases the second plug 336 against the spring member(s) 360 to provide direct contact there between. This approach eliminates the non-zero, predetermined gap of the ESC shown in FIG. 2.

As described above, the top plate 216 is positioned with a very high degree of accuracy relative to the baseplate 210 to prevent tilt. In other words, the top plate 216 is precisely oriented relative to the baseplate 210 to ensure a level surface for processing the substrate 224. The top plate 216 biases the second plug 336 downwardly in a vertical direction against the spring member(s) 360 during assembly allowing the top plate 216 to be oriented correctly relative to the baseplate 210. In other words, direct contact occurs between the bottom surface of the top plate 216 and the second plug 336 (unlike the approach in FIG. 2). This arrangement allows the predetermined gap shown in FIG. 2 to be eliminated, which reduces residue generation and clogging.

Direct contact between the second plug 336 and the bottom surface of the top plate 216 (at 372) prevents or significantly reduces exposure of the bonding material 260 and/or the gasket 264 to the reactive species. Further, to the extent that some exposure still occurs, the residue will build up (if at all) in other locations (such as along an outer edge 374 of the second plug). This type of clogging is self-sealing. In other words, the residue that is generated in response to exposure to the active species is drawn into pores of the ceramic and cause sealing that prevents further residue generation and clogging. In effect, the ESC 300 has self-sealing gas conduits.

In FIG. 4, another ESC 400 is shown that is similar to the ESC 300 except that a second plug 410 is made of porous ceramic instead of non-porous ceramic as in FIG. 3. Direct contact between the second plug 410 and the bottom surface of the top plate 216 (at 372) prevents or significantly reduces exposure of the bonding material 260 and/or the gasket 264 to the reactive species. Further, to the extent that some exposure still occurs, the residue will build up (if at all) in other locations (such as along an outer edge 374 of the second plug 410) and cause clogging that will prevent further residue generation and clogging. In effect, the ESC 400 has self-sealing gas conduits. In this example, the inlet 240 and/or the outlet 244 are not chamfered or widened relative to the gas through-hole 242.

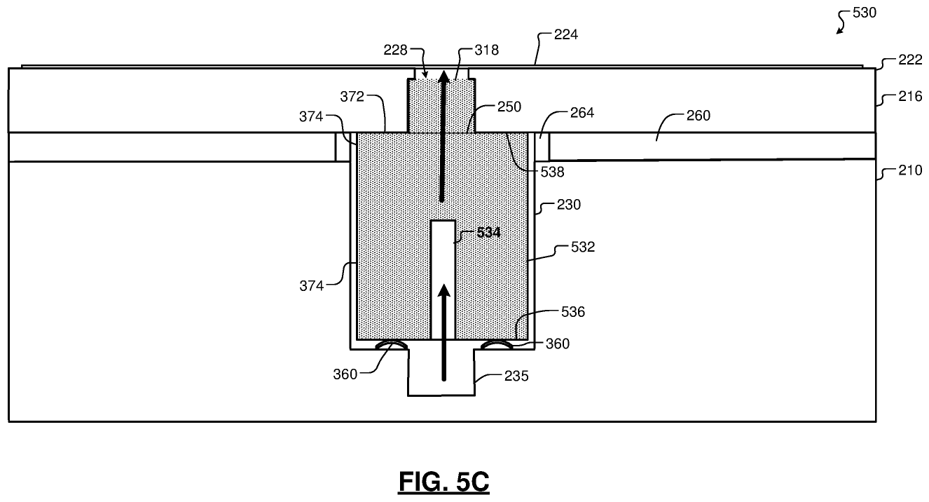

Referring now to FIGS. 5A to 5D, other variations of the ESC can be used. In FIG. 5A, an ESC 500 is shown to include a second plug 510 having a cylindrical shape. The second plug 510 rests on the spring member(s) 360 in the cavity 230 as described above. The second plug 510 includes a top surface that is biased by the spring member(s) 360 against a bottom surface of the top plate 216. In this example, the second plug 510 is made of porous ceramic and does not include a gas through-hole. Further, the ESC 500 does not include a gasket. As can be seen, the bonding material 260 may flow partially downwardly before curing into a gap between an outer surface of the second plug 510 and vertical surfaces of the cavity 230. In FIG. 5B, an ESC 520 includes the gasket 264. The gasket 264 is used to contain the bonding material 260 as described above.

In FIGS. 5C and 5D, the second plug can include a gas through-hole having varying lengths relative to a height of the second plug. In FIG. 5C, an ESC 530 includes a second plug 532 that is made of a porous ceramic and includes a gas through-hole 534 that extends from a bottom surface 536 of the second plug 532 partially towards a top surface 538 of the second plug 532. In FIG. 5D, an ESC 540 includes a second plug 542 that is made of a porous ceramic and includes a gas through-hole 544 that extends from a bottom surface 546 of the second plug 542 to a top surface 548 of the second plug 542.

Direct contact between the second plugs 510, 532 and 542 and the bottom surface of the top plate 216 (at 372) prevents or significantly reduces exposure of the bonding material 260 and/or the gasket 264 to the reactive species. Further, to the extent that some exposure still occurs, the residue will build up (if at all) in other locations (such as along an outer edge 374 of the second plugs 510, 532 and 542) and cause clogging that will prevent further residue generation and clogging. In effect, the ESCs 500, 520, 530 and 540 have self-sealing gas conduits. Further, since the bonding material 234 in FIG. 2 is eliminated, it cannot produce residue.

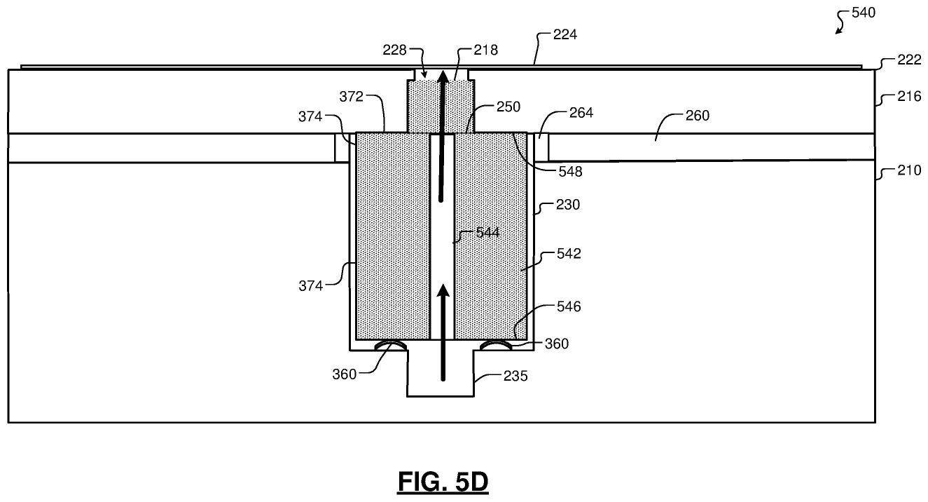

Referring now to FIG. 6, an ESC 600 includes a second plug 610. The second plug 610 has a cylindrical body with a radially outer portion 612 and a radially inner portion 614. In some examples, the radially outer portion 612 is made of non-porous ceramic and the radially inner portion 614 is made of porous ceramic. In some examples, the radially inner portion 614 comprises in-situ porous ceramic. In other examples, the radially inner portion 614 is bonded inside the radially outer portion 612. A radially outer surface of the second plug 610 includes an annular cavity 618 to receive the bonding material 260 during assembly. While a particular location of the annular cavity 618 is shown, the annular cavity 618 can be in arranged in other locations such as immediately adjacent to a top surface of the second plug 610 or in other locations (e.g., near a top surface of the baseplate 210). In some examples, the one or more spring members 360 are located under the radially outer portion 612. The radially inner portion 614 can include no gas through-hole and the gas flows through the pores embedded therein. Alternately, a partial gas through-hole or a gas through-hole that extends vertically all of the way through the second plug 610 can be used.

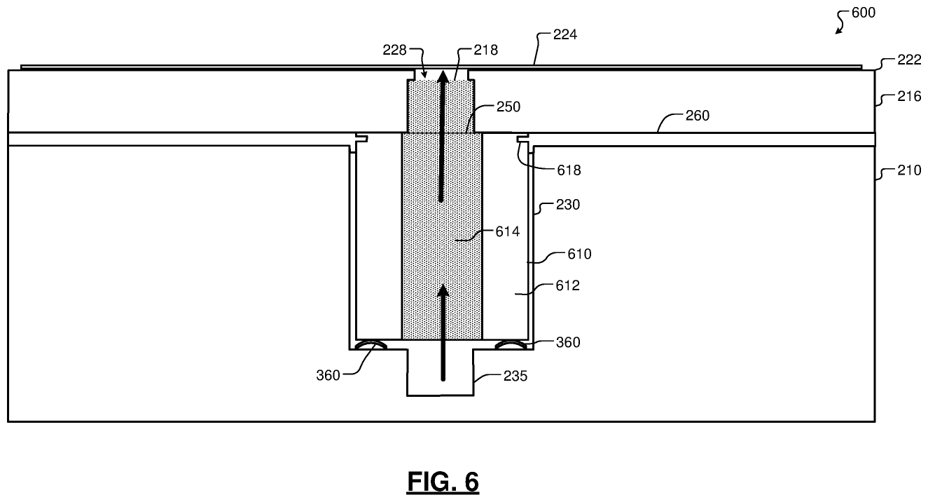

Referring now to FIG. 7, an ESC 700 includes a second plug 710 and a sleeve 714 located around an outer surface of the second plug 710. In some examples, a gap is formed therebetween. The sleeve 714 and the second plug 710 are separately supported and can move independently. In some examples, the sleeve 714 is made of non-porous ceramic and the second plug 710 is made of porous ceramic. In some examples, a radially outer surface of the sleeve 714 includes an annular cavity 718 on a radially outer surface thereof to receive the bonding material 260 during assembly. In some examples, a spring member(s) 360-1 is located under the second plug 710 and a spring member(s) 360-2 is located under the sleeve 714. The radially inner portion 614 includes no gas through-holes, a partial gas through-hole or a full gas through-hole.

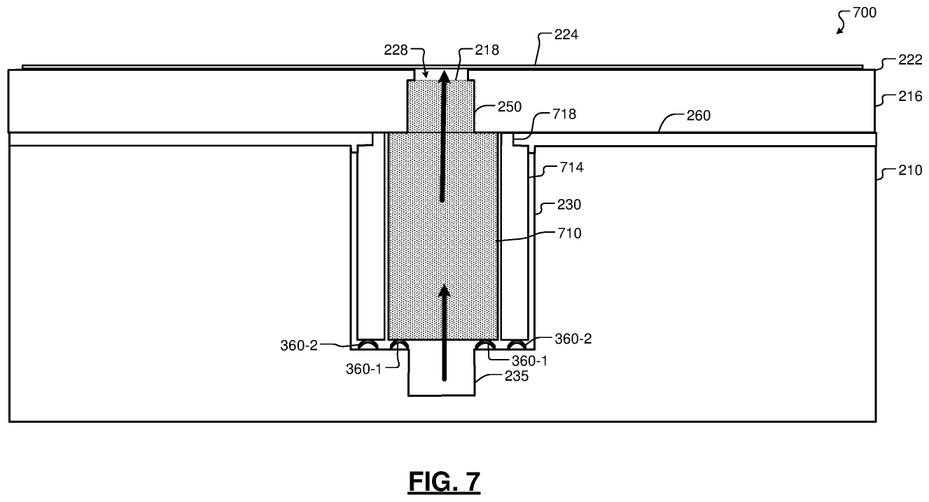

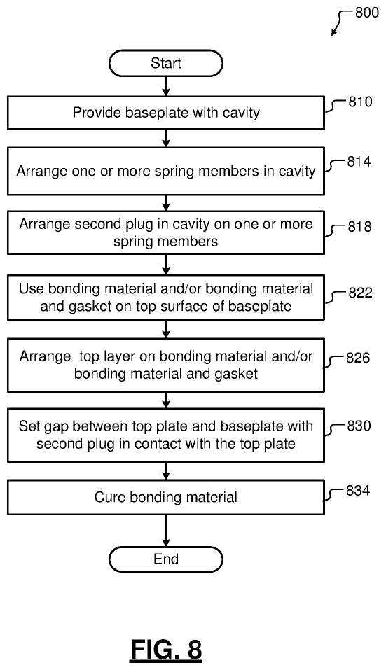

Referring now to FIG. 8, a method 800 for making an ESC includes providing a baseplate with a cavity at 810. At 814, one or more spring members are arranged on a bottom surface of the cavity. At 818, the second plug is arranged in the cavity on the one or more spring members. If a ceramic sleeve is used, the ceramic sleeve is arranged around the second plug or the ceramic sleeve is inserted first and the second plug is inserted into the ceramic sleeve.

At 822, a bonding material is applied to a top surface of the baseplate (or a gasket is arranged on the baseplate and the bonding material is applied). The top plate is arranged on the bonding material and/or the gasket at 826. A bottom surface of the top plate is in direct contact with a top surface of the second plug. At 830, outer edges of the top plate and the baseplate are aligned and a predetermined vertical gap is set between radially outer edges of the top plate and the baseplate. At 834, the bonding material is cured.

The ESC with self-sealing gas conduits according to the present disclosure significantly reduces or eliminates clogging. If clogging occurs, it occurs in locations where it will not significantly affect gas flow and/or ESC functionality. In some examples described herein, the clogging seals gaps or pores so that the effect of any further clogging becomes insignificant to gas flow.

In some examples, the top surface of the second plug directly contacts the bottom surface of the top plate (at the first plug). The ESC according to the present disclosure reduces the gap that was previously used (and where clogging typically occurred). The ESC according to the present disclosure provides a longer path for the reactive species to cover before reaching and reacting with the bonding material and/or gaskets. Therefore, less clogging residue is created during use.

In some examples, the second plug may be made of porous ceramic (with or without a gas through-hole). In some examples, the second plug and/or the sleeve include annular cavities or other features that serve as a dam to control overflow of viscous bonding material during the ESC bonding process allowing the gasket to be eliminated.

In some examples, the second plug is made of porous ceramic plug and includes no gas through-hole, a partial gas through-hole or a gas through-hole passing through the second plug. In some examples, the second plug has a larger diameter than the first plug. As a result, the location of clogging residue (if it occurs) will be limited to the outside circumference of the second plug and will not block the flow of gas.

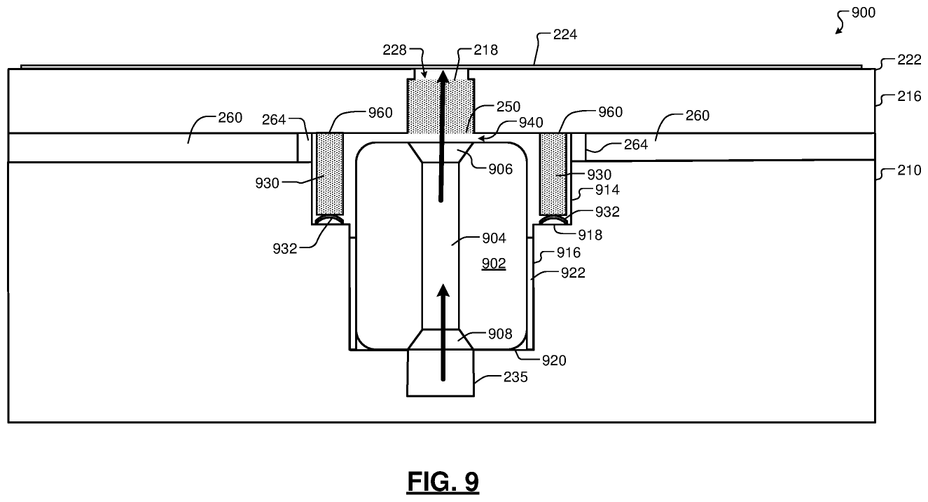

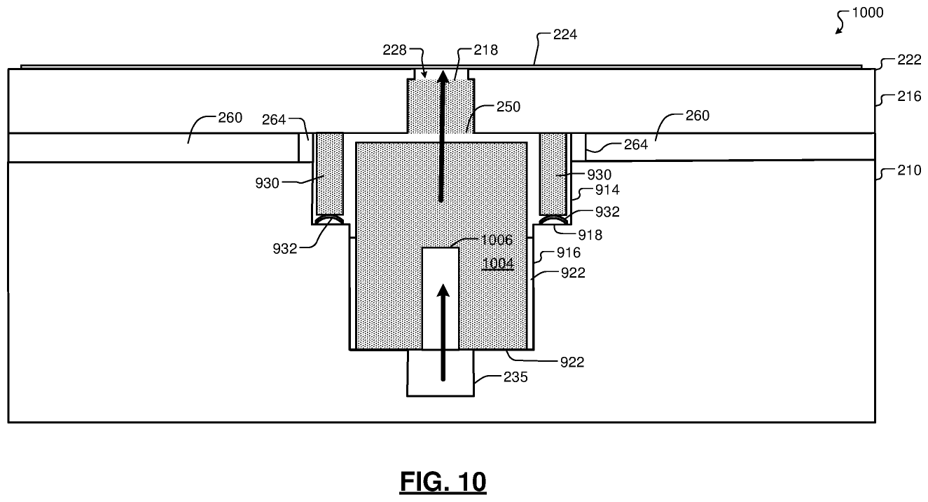

Referring now to FIGS. 9-10, the second plug can also be used with a gap between the top surface thereof and a bottom surface of the top plate. A baseplate includes an upper cavity and a lower cavity that are concentric. A sleeve is arranged on one or more spring members around the second plug. A top surface of the sleeve is biased by the one or more spring members against a bottom surface of the top plate. The second plug is made of porous or non-porous ceramic, although other suitable materials can be used.

In FIG. 9, an ESC 900 includes a second plug 902 including a gas through-hole 904. An inlet 908 and an outlet 906 of the gas through-hole 904 may be angled or chamfered as shown relative to a diameter of the gas through-hole 904 or a straight gas through-hole can be used. In this example, the second plug 902 is made of non-porous material such as non-porous ceramic.

The baseplate 210 defines a cavity including a first cavity portion 914 and a second cavity portion 916 located radially outside of the first cavity portion 914. The first cavity portion 914 includes a first annular surface 918 that is generally parallel to the substrate supporting surface. The second cavity portion 916 of the cavity includes a second annular surface 920 that is generally parallel to the substrate supporting surface.

In some examples, the first cavity portion 914 is shallower than the second cavity portion 916. In some examples, the second plug 902 can be bonded to side surfaces of the second cavity portion 916 using bonding material 922. In the example in FIG. 9, the first cavity portion 914 corresponds to an upper cavity and the second cavity portion 916 corresponds to a lower cavity (in addition to the cavity 235) and the cavities 235, 914 and 916 are concentric. In some examples, the bonding material 922 includes epoxy, although other types of bonding material can be used. In other examples, the second plug 902 is not bonded to the side surfaces of the second cavity portion 916.

A sleeve 930 has an annular body and is located around an outer surface of the second plug 902. In some examples, the sleeve 930 is made of a porous material such as porous ceramic. In the example in FIG. 9, the second plug 902 is taller than the sleeve 930 and is bonded to the side surfaces of the second cavity portion 916. If the second plug 902 does not need to be bonded to the side surfaces 922, the first cavity portion 914 can have the same height as the second cavity portion 916 (similar to FIG. 7) and the first cavity portion 914 and the second cavity portion form a single cavity (with no intervening surface to bond the second plug 902). Alternately, the sleeve 930 can be taller than the second plug 902 and the first cavity portion 914 can be taller than the second cavity portion 916. In other words, the sleeve 930 can be vertically taller, the same height or shorter than the second plug 902.

In some examples, one or more spring members 932 are located on the first annular surface 918. The one or more spring members 932 bias the sleeve 930 against a lower surface of the top plate 216 when the top plate 216 is attached to the baseplate 210.

In some examples, the second plug 902 is in direct contact with the second annular surface 922. However, a gap 940 is formed between a top surface of the second plug 902 and the bottom surface of the top plate 216. The gap 940 is provided so that the second plug 902 does not affect the positioning of the top plate 216 relative to the baseplate 210 during assembly and/or so that relative movement of the second plug 902 and the bottom surface of the top plate 216 can occur without contact. In other words, this arrangement avoids potential particle generation caused by direct contact between the second plug 902 and the bottom surface of the top plate 216. In some examples, the gap 940 is minimized and is as small as possible without adversely affecting the positioning of the top plate 216 relative to the baseplate 210 and/or allowing contact causing particle generation.

If active species reach the gasket 264 and/or the bonding material 260 and generate residue, the residue will tend to clog and seal an annular abutting surface at 960 between the top surface of the sleeve 930 and the bottom surface of the top plate 216. While the sleeve 930 and the bottom surface of the top plate 216 have an annular-shaped contact surface, the potential for particle generation is reduced due to a smaller surface area of an annular contact patch (as compared to the circular contact patch between the second plug and the bottom surface of the top plate 216 as in other examples).

In FIG. 10, a similar arrangement is shown using a second plug 1004 that is made of a porous material such as porous ceramic. The second plug 1004 may include no gas through-hole, a partial gas through-hole 1006 (shown), or a full gas through-hole. As in FIG. 9, the sleeve 930 is arranged around the second plug 1004 and is biased by the one or more spring members 932 into a bottom surface of the top plate 216.

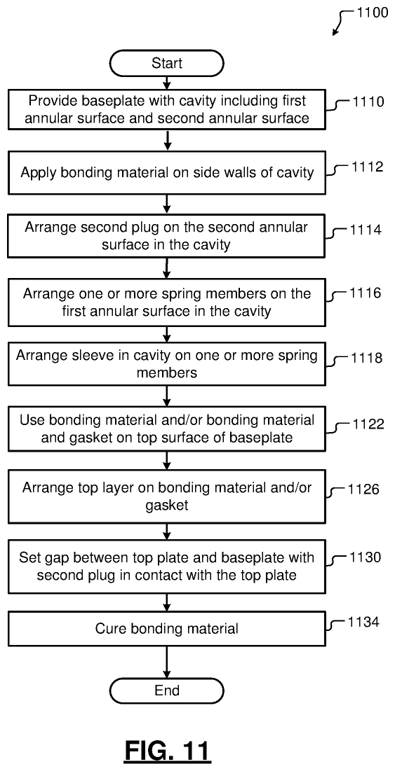

Referring now to FIG. 11, a method 1100 for making an ESC includes providing a baseplate with a cavity at 1110. The cavity includes a first cavity portion including a first annular surface that is located radially outside of a second annular surface of a second cavity portion. At 1112, bonding material is applied to side walls of second cavity portion and/or side walls of the second plug. Alternately, step 1112 can be performed after 1118 and the bonding material can be injected after the second plug is installed.

At 1114, the second plug is inserted into the second cavity portion with a bottom surface thereof resting on the second annular surface. At 1116, one or more spring members are arranged on the first annular surface of the first cavity portion. At 1118, the sleeve is arranged on the one or more spring members.

At 1122, a bonding material is applied to a top surface of the baseplate (or a gasket is arranged on the baseplate and the bonding material is applied). The top plate is arranged on the bonding material and/or the gasket at 1126. A bottom surface of the top plate is in direct contact with the sleeve. At 1130, outer edges of the top plate and the baseplate are aligned and a predetermined vertical gap is set between radially outer edges of the top plate and the baseplate. At 1134, the bonding material is cured.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1. An electrostatic chuck for a substrate, comprising:
a baseplate including a first surface and a cavity arranged on the first surface;
a top plate including a first plug;
one or more spring members including a first spring member arranged in the cavity;
a second plug arranged between the top plate and the first spring member; and
a bonding material attaching the top plate to the first surface of the baseplate.

2. The electrostatic chuck of claim 1, wherein the first spring member biases the second plug into direct contact with a second surface of the top plate and wherein the top plate, the first plug and the second plug are made of ceramic.

3. The electrostatic chuck of claim 1, further comprising a gasket arranged around the cavity between the top plate and the baseplate, wherein the bonding material is located radially outside of the gasket.

4. The electrostatic chuck of claim 1, wherein the first plug is made of porous ceramic and is formed insitu in the top plate.

5. The electrostatic chuck of claim 1, wherein the second plug is made of porous ceramic.

6. The electrostatic chuck of claim 1, wherein the second plug has a diameter that is greater than a diameter of the first plug.

7. The electrostatic chuck of claim 1, wherein the second plug includes an annular outer channel formed on a radially outer surface thereof to receive the bonding material.

8. The electrostatic chuck of claim 1, wherein the second plug is made of porous ceramic and does not include a gas through-hole.

9. The electrostatic chuck of claim 1, wherein the second plug is made of porous ceramic and includes a gas through-hole that extends partially through the second plug.

10. The electrostatic chuck of claim 1, wherein the second plug is made of porous ceramic and includes a gas through-hole that extends through the second plug.

11. The electrostatic chuck of claim 1, wherein the second plug includes a cylindrical body with a radially outer portion made of non-porous ceramic and a radially inner portion made of porous ceramic.

12. The electrostatic chuck of claim 1, further comprising a sleeve arranged between the second plug and side surfaces of the cavity.

13. The electrostatic chuck of claim 12, further comprising a second spring member arranged in the cavity to bias the sleeve against the top plate.

14. The electrostatic chuck of claim 12, wherein the second plug is made of porous ceramic.

15. The electrostatic chuck of claim 12, wherein the sleeve is made of ceramic.

16. A method of making an electrostatic chuck for a substrate, comprising:
providing a baseplate including a first surface and a cavity arranged on the first surface;
providing a top plate including a first plug;
arranging a first spring member in the cavity;
arranging a second plug between the top plate and the first spring member; and
attaching the top plate to the first surface of the baseplate using a bonding material.

17. The method of claim 16, further comprising biasing the second plug into direct contact with a second surface of the top plate using the first spring member, wherein the top plate, the first plug and the second plug are made of ceramic.

18. The method of claim 16, further comprising arranging a gasket around the cavity between the top plate and the baseplate prior to using the bonding material.

19. The method of claim 16, further comprising forming the first plug insitu in the top plate, wherein the first plug is made of porous ceramic.

20. The method of claim 16, wherein the second plug is made of porous ceramic.

21. The method of claim 16, wherein the second plug has a diameter that is greater than a diameter of the first plug.

22. The method of claim 16, further comprising forming an annular channel on a radially outer surface of the second plug to receive the bonding material.

23. The method of claim 16, wherein the second plug is made of porous ceramic and does not include a gas through-hole.

24. The method of claim 16, wherein the second plug is made of porous ceramic and includes a gas through-hole extending partially through the second plug.

25. The method of claim 16, wherein the second plug is made of porous ceramic and includes a gas through-hole extending through the second plug.

26. The method of claim 16, wherein the second plug includes a cylindrical body with a radially outer portion made of non-porous ceramic and a radially inner portion made of porous ceramic.

27. The method of claim 16, further comprising arranging a sleeve between the second plug and side surfaces of the cavity.

28. The method of claim 27, further comprising biasing the sleeve against the top plate using a second spring member.

29. The method of claim 27, wherein the second plug is made of porous ceramic.

30. The method of claim 27, wherein the sleeve is made of ceramic.

31. An electrostatic chuck for a substrate, comprising:
a baseplate including a first surface and a cavity arranged on the first surface,
wherein the cavity includes a first cavity portion defining a first annular surface and a second cavity portion defining a second annular surface;
a top plate including a first plug;
a first spring member arranged on the first annular surface in the first cavity portion;
a second plug arranged on the second annular surface between the top plate and the second annular surface;
a sleeve arranged around the second plug and on the first spring member; and
a bonding material attaching the top plate to the first surface of the baseplate.

32. The electrostatic chuck of claim 31, wherein the first spring member biases a top surface of the sleeve into direct contact with a bottom surface of the top plate.

33. The electrostatic chuck of claim 31, further comprising a gasket arranged around the cavity between the top plate and the baseplate, wherein the bonding material is located radially outside of the gasket.

34. The electrostatic chuck of claim 31, wherein the first plug is made of porous ceramic and is formed insitu in the top plate.

35. The electrostatic chuck of claim 31, wherein the second plug has a diameter that is greater than a diameter of the first plug.

36. The electrostatic chuck of claim 31, further comprising bonding material to bond the second plug to side walls of the second cavity portion.

37. The electrostatic chuck of claim 31, wherein the second plug is made of porous ceramic and does not include a gas through-hole.

38. The electrostatic chuck of claim 31, wherein the second plug is made of porous ceramic and includes a gas through-hole that extends partially through the second plug.

39. The electrostatic chuck of claim 31, wherein the second plug is made of porous ceramic and includes a gas through-hole that extends through the second plug.

40. The electrostatic chuck of claim 31, wherein the second plug is made of non-porous ceramic and includes a gas through-hole that extends through the second plug.

41. A method for making an electrostatic chuck for a substrate, comprising:
providing a baseplate including a first surface and a cavity arranged on the first surface,
wherein the cavity includes a first cavity portion defining a first annular surface and a second cavity portion defining a second annular surface;
providing a top plate including a first plug;
arranging a first spring member on the first annular surface in the first cavity portion;
arranging a second plug on the second annular surface between the top plate and the second annular surface;
arranging a sleeve around the second plug and on the first spring member; and
bonding the top plate to the first surface of the baseplate.

42. The method of claim 41, further comprising biasing the sleeve into direct contact with a bottom surface of the top plate using the first spring member.

43. The method of claim 42, wherein a gap is defined between a top surface of the second plug and the bottom surface of the top plate when the top plate is bonded to the baseplate.

44. The method of claim 41, further comprising arranging a gasket around the cavity between the top plate and the baseplate, wherein bonding material is located radially outside of the gasket.

45. The method of claim 41, wherein the first plug is made of porous ceramic and is formed insitu in the top plate.

46. The method of claim 41, wherein the second plug has a diameter that is greater than a diameter of the first plug.

47. The method of claim 41, wherein the second plug is made of porous ceramic and does not include a gas through-hole.

48. The method of claim 41, wherein the second plug is made of porous ceramic and includes a gas through-hole that extends one of partially through the second plug and through the second plug.

49. The method of claim 41, wherein the second plug is made of non-porous ceramic and includes a gas through-hole that extends through the second plug.

50. The method of claim 41, further comprising bonding the second plug to side walls of the second cavity portion.
